(19) United States
(12) Patent Application Publication
(10) Pub. No.: US 2008/0284009 A1
(43) Pub. Date: Nov. 20, 2008

(54) Dimple free gold bump for drive IC

(76) Inventor: Heikyung Min, Palo Alto, CA (US)

Correspondence Address: STALLMAN & POLLOCK LLP;Attn: Michael J. Pollock, 353 Sacramento Street, Suite 2200, San Francisco, CA, 94111, US

(21) Appl. No.: 11/803,768

(22) Filed: May 16, 2007

(51) Int. Cl. H01L 23/482; H01L 21/60

(52) U.S. Cl. 257/737; 438/613; 257/E23.02; 257/E23.021; 257/E21.506

(57) ABSTRACT

A conductive bump structure for an integrated circuit (IC) structure comprises a passivation layer, such as a silicon oxide/silicon nitride stack, that is formed on an upper surface of each of the conductive contact pads (e.g. Al pads) of the IC. A plurality of openings extend through the passivation layer to expose areas of the upper surface of the contact pad. The openings are larger in the longitudinal dimension than in the lateral dimension. A conductive bump, preferably comprising gold (Au), is formed on the passivation layer to extend through the openings in the passivation and into electrical contact with the exposed upper surface areas of the contact pad.

### FIELD OF THE INVENTION

The present invention relates to integrated circuits and, in particular, to a contact design for use, for example, in a drive integrated circuit.

### DISCUSSION OF THE RELATED ART

Many hand-held devices, such as cellular telephones, include a display that provides images in response to signals received from drive integrated circuits (ICs) that are included in the electronics of the device. Typically, the drive ICs are electrically connected to conductive solder balls formed on the back side of the glass display panel through an array of contact “bumps” that are formed as part of the drive IC structure and are connected to the conductive interconnect structure of the drive circuitry.

FIG. 1A shows a cross section of a conductive bump design that is widely utilized in drive ICs. The design includes a gold (Au) bump 100 that is formed in electrical contact with a conductive pad 102, e.g. aluminum (Al), that is part of the interconnect structure of an associated integrated circuit structure 104, e.g. a drive IC. An opening formed in an underlying passivation layer 106 enables the electrical contact between the Au bump 100 and the Al pad 102. The passivation layer 106 typically comprises a silicon nitride layer formed on a silicon oxide layer. The wide-area opening in the passivation layer 106 enables relatively low impedance current flow between the Au bump 100 and the Al pad 102.

However, formation of the wide opening in the passivation layer 106 results in a “step” structure 106a around the periphery of the Al pad 102. During the formation of the Au bump 100, this step in the passivation layer 106 causes a corresponding step 100a to be formed around the periphery of the Au bump 100, thereby defining a recessed “dimple” surface area 100b at the inner portion of the gold bump 100. As shown in the FIG. 1A example, for a 1.4 μm step height in the passivation layer 106, and for an Au bump height of 15 μm, the dimple surface 100b of the Au bump 100 can be recessed by a depth of 1.4 μm from the surrounding peripheral step 100a.

The above-described Au bump dimple 100b can create performance problems for the associated IC. Those skilled in the art will appreciate that the IC will typically include a large number of spaced apart Au bumps that are distributed across the layout of the IC. In the ideal case, shown in FIG. 1B, all of these multiple Au bumps 100 will align to establish electrical contact between each of the multiple bumps 100 and a corresponding conductive solder ball 110 of the associated display circuitry. However, as shown in FIG. 1C, misalignment that can result from the IC fabrication process may cause some of the Au bumps 100 to align such that the peripheral step 100a of the bump 100 is in contact with a corresponding solder ball 110 (ACF—Anisotropic Conductive Film), while other Au bumps, e.g., bump 112 in FIG. 1C, have the dimple surface of the bump 112 aligned with its corresponding solder ball 110. This can result in a gap between the dimple surface of the Au bump 112 and the solder ball 110, creating an “open” circuit. Thus, the occurrence of only one such gap in the connection of the drive IC to the display panel can cause complete failure of the device (e.g. cellular telephone).

FIGS. 2A and 2B illustrate a known approach to addressing the misalignment problem discussed above. Rather then utilizing one wide-area opening in the passivation layer, as shown in the FIG. 1 approach, this approach utilizes an array of small squares 202 (FIG. 2A) or an array of small circles 204 (FIG. 2B) formed in the passivation layer 200 over the conductive contact pad 206. As shown in FIG. 2C, since the size of each of the openings in the passivation layer 200 is relatively small (e.g., 3 μm×3 μm with minimum 10 μm spacing between openings), formation of the Au bump 208 over the openings results in a relatively flat upper surface 208a of the bump 208 while still providing electrical contact between the Au bump 208 and the contact pad 206 through the openings. This flat upper surface 208a of the Au bump 208 resolves the misalignment problem discussed above.

The problem with this approach is that, since current flow is proportional to the cross sectional area of the conductor, the reduced area provided by the FIG. 2C design results in a higher impedance current path between the Au bump 208 and the contact pad 206.

Thus, it would be desirable to have available an Au bump design that solves the above-discussed misalignment problem, but maintains adequate current flow between the Au bump and the associated IC.

### SUMMARY OF THE INVENTION

The present invention provides a conductive bump structure for an integrated circuit (IC) structure, e.g. a drive IC. The bump structure comprises a passivation layer, such as a silicon oxide/silicon nitride stack, formed over each of the conductive contact pads (e.g., aluminum) of the IC. A plurality of openings are formed over each pad through the passivation layer to expose areas of the upper surface of the pad. The openings are larger in the longitudinal dimension than in the lateral dimension. For each pad, a conductive bump, preferably comprising gold (Au), is formed on the passivation layer to extend through the openings in the passivation layer and into electrical contact with the exposed upper surface areas of the pad.

In accordance with the invention, the openings in the passivation layer are large enough to provide a total cross sectional area that enables adequate current flow between each aluminum contact pad and its associated gold bump, yet small enough to facilitate fabrication of a gold bump having a relatively flat upper surface area, thereby eliminating the misalignment problems associated with “dimple” bumps.

The features and advantages of the various aspects of the present invention will be more fully understood and appreciated upon consideration of the following detailed description of the invention and the accompanying drawings, which set forth an illustrative embodiment in which the concepts of the invention are utilized.

### DESCRIPTION OF THE DRAWINGS

FIG. 1A is a partial cross section drawing illustrating a known gold (Au) bump structure.

FIG. 1B is a partial cross section drawing illustrating ideal alignment between an array of Au bumps of the type shown in FIG. 1 and a corresponding solder ball array of an associated conductive structure.

FIG. 1C is a partial cross section drawing illustrating misalignment between an array of Au bumps of the type shown in FIG. 1 and a corresponding solder ball array of an associated conductive structure.

FIG. 2A is a top view drawing illustrating a known approach to Au bump formation that utilizes an array of squares formed in the passivation layer.

FIG. 2B is a top view drawing illustrating an approach to Au bump formation that utilizes an array of circles formed in the passivation layer.

FIG. 2C is a partial cross section drawing illustrating an Au bump structure resulting from the FIG. 2A or the FIG. 2B approach.

FIG. 3A is a top view drawing illustrating a method of fabricating an Au bump structure in accordance with the present invention using an array of rectangular openings in the passivation layer.

FIG. 3B is a top view drawing illustrating a method of fabricating an Au bump structure in accordance with the present invention using a sequence of full length openings in the passivation layer.

FIG. 3C is a top view drawing illustrating a method of fabricating an Au bump structure in accordance with the present invention utilizing an array of oval openings in the passivation layer.

FIG. 3D is a partial cross section drawings illustrating an Au bump structure fabricated in accordance with the concepts of the present invention.

### DETAILED DESCRIPTION OF THE INVENTION

The present invention provides a conductive bump structure for use in an integrated circuit structure. The bump structure eliminates the previously-encountered misalignment problems associated with attaching the IC to another conductive structure, but at the same time permits sufficient current flow through the bump structure. The IC may be, for example, a drive IC of the type utilized to drive the display of a hand-held device such as a cellular telephone. The other conductive structure may be, for example, the display panel electronics of a hand-held device. Those skilled in the art will appreciate that the concepts of the invention are not limited to this particular product application.

A conductive bump structure in accordance with the invention comprises a passivation layer that is formed over each of the conductive contact pads of the IC structure. A plurality of openings extend through the passivation layer to expose areas of the upper surface of the contact pad. As discussed in greater detail below, the openings are larger in the longitudinal direction than in the lateral direction. For each contact pad, a conductive bump is formed on the passivation layer to extend through the openings in the passivation layer and into electrical contact with the exposed upper surface areas of the contact pad.

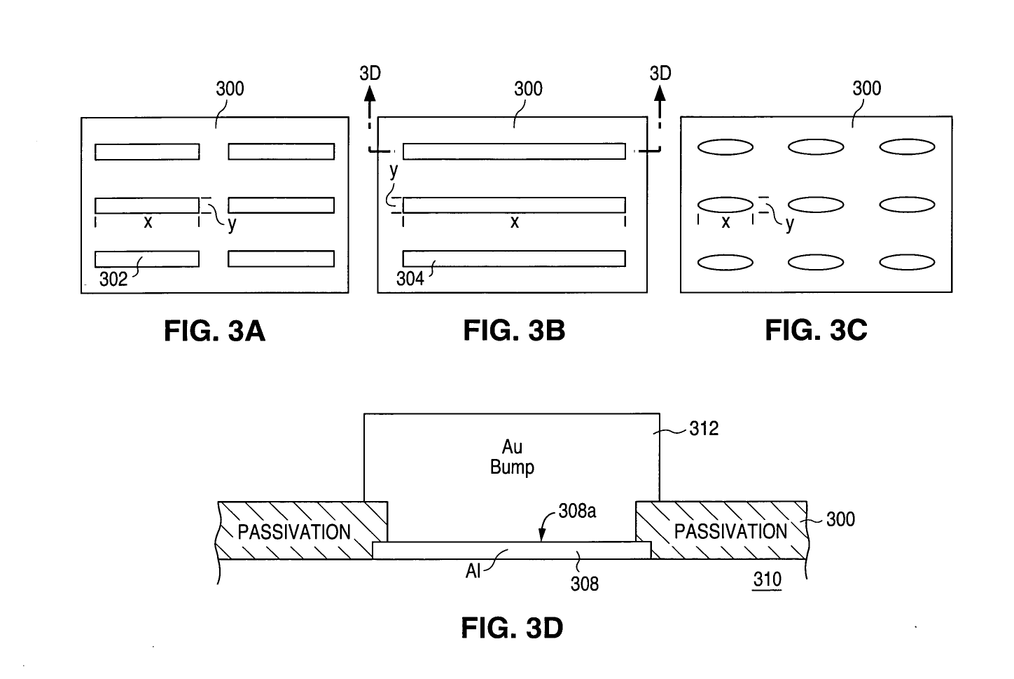

As indicated above, a key aspect of the present invention is the geometry of the openings formed in the passivation layer between the conductive bump and the underlying contact pad. FIGS. 3A, 3B and 3C show three exemplary embodiments of such openings in the passivation layer 300. FIG. 3A shows an array of rectangular openings 302 arranged in three rows of two rectangular openings 302 per row. FIG. 3B shows a sequence of three rectangular openings 304, with each rectangular opening 304 formed to extend substantially the entire length of the underlying contact pad. FIG. 3C shows an array of oval openings 306 arranged in three rows of three ovals openings 306 per row. In each of the embodiments of the invention shown in FIGS. 3A, 3B and 3C, the openings have a longitudinal dimension x that is greater than the lateral dimension y.

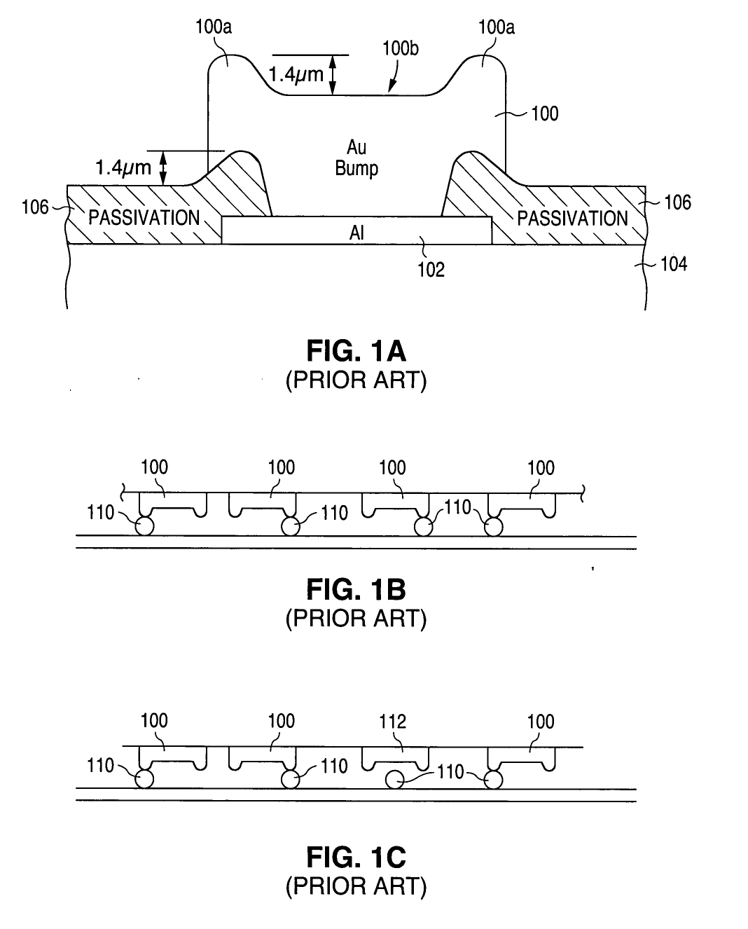

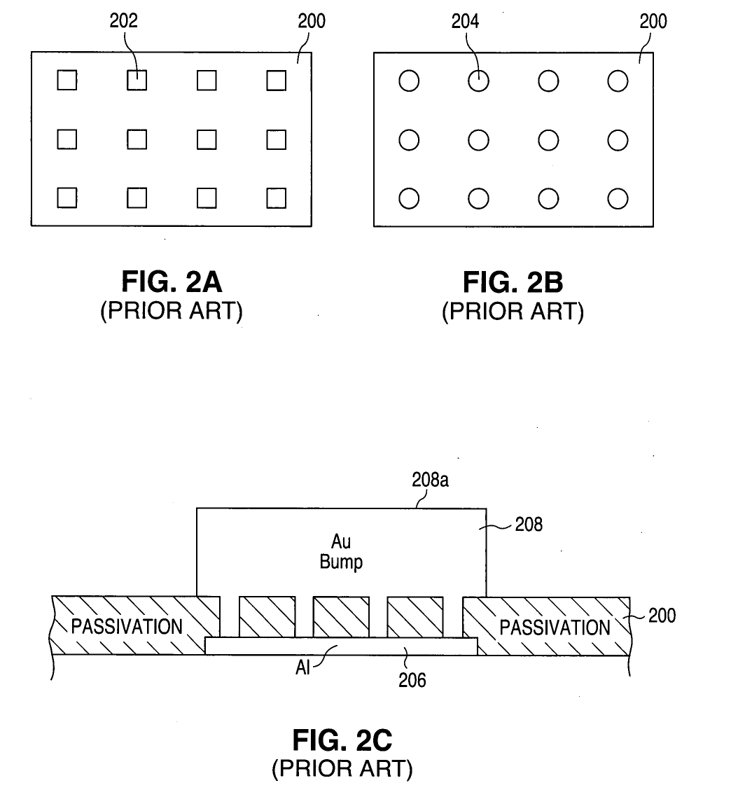

As mentioned above, current flow in the gold structure is proportional to the area of the opening in the passivation layer. For example, for a contact pad that is 80 μm×31 μm, the FIG. 1A pad opening is 522 square μm, but has the above-described dimple problem. For the same pad size, the FIG. 2B approach utilizes six 3 μm diameter circles to provide a total passivation opening of 42.4 square μm. In accordance with the techniques of the present invention, for the same pad size, the total area of the passivation opening can be up to 348 square μm.

FIG. 3D shows a cross section of a conductive bump structure in accordance with the present invention, in this case taken along the line 3D-3D in FIG. 3B. As discussed above, the FIG. 3D structure includes a passivation layer 300 formed over a conductive contact pad 308 of an associated integrated circuit structure 310, e.g. a drive IC for the display of hand-held device. The conductive pad is preferably formed of aluminum or an aluminum alloy, although those skilled in the art will appreciate that other conductive materials may be utilized. The passivation layer 300 preferably comprises a silicon oxide layer formed over the conductive pad 308 and a silicon nitride layer formed over the silicon oxide layer. The openings discussed above are formed in the passivation layer 300 to expose surface areas 308a of the conductive pad 308. Those skilled in the art will appreciate that the openings can be etched through the passivation layer utilizing conventional IC processing techniques. As discussed above, the openings have a longitudinal dimension that is greater than the lateral dimension. A conductive bump 312, preferably gold (Au), is formed (by conventional techniques well known to those skilled in the art) on the passivation layer 300 to extend through the openings in the passivation layer 300 and into electrical contact with the exposed surface areas 308a of the contact pad 308. While Au is the preferred material for the bump 312, those skilled in the art will appreciate that other materials can also be used for this purpose.

In summary, the present invention provides a conductive bump structure that solves the “dimple” problem caused by the underlying passivation steps, while maintaining the required contact area between the bump and the IC contact pads.

It should be understood that the particular embodiments of the invention described above have been provided by way of example and that other modifications may occur to those skilled in the art without departing from the scope and spirit of the invention as express in the appended claims and their equivalents.

What is claimed is:

1. A conductive bump structure formed as part of an integrated circuit structure, the integrated circuit structure including at least one conductive pad, the conductive bump structure comprising:
a passivation layer formed on an upper surface of the conductive pad, the passivation layer including a plurality of openings formed therethrough to expose areas of the upper surface of the conductive pad, each of the openings having a longitudinal dimension and a lateral dimension that is perpendicular to the longitudinal dimension, the longitudinal dimension being greater than the lateral dimension; and
a conductive bump formed on an upper surface of the passivation layer, the conductive bump extending through the openings in the passivation layer and into electrical contact with the exposed upper surface areas of the contact pad.

2. A conductive bump structure as in claim 1, and wherein the conductive bump comprises gold (Au).

3. A conductive bump structure as in claim 1, and wherein the passivation layer comprises a silicon oxide layer formed on the upper surface of the contact pad and a silicon nitride layer formed on the silicon oxide layer.

4. A conductive bump structure as in claim 1, and wherein the contact pad comprises aluminum (Al).

5. A conductive bump structure as in claim 1, and wherein the openings are rectangles.

6. A conductive bump structure as in claim 1, and wherein the openings are ovals.

7. A method of forming a conductive bump structure for an integrated circuit structure, the integrated circuit structure including at least one conductive pad, the method comprising:
forming a passivation layer on an upper surface of the conductive pad, the passivation layer including a plurality of openings formed therethrough to expose areas of the upper surface of the conductive pad, each of the openings having a longitudinal dimension and a lateral dimension that is perpendicular to the longitudinal dimension, the longitudinal dimension being greater than the lateral dimension; and
forming a conductive bump on an upper surface of the passivation layer such that the conductive bump extends through the openings in the passivation layer and into electrical contact with the exposed upper surface areas of the contact pad.

8. A method as in claim 7, and wherein the conductive bump comprises gold (Au).

9. A method as in claim 7, and wherein the step of forming a passivation layer comprises:
forming a silicon oxide layer on the upper surface of the contact pad;
forming a silicon nitride layer on the silicon oxide layer; and
forming the openings through the silicon nitride layer and the silicon oxide layer.

10. A method as in claim 7, and wherein the contact pad comprises aluminum (Al).

11. A method as in claim 7, and wherein the openings are rectangles.

12. A method as in claim 7, and wherein the openings are ovals.
